(19) United States
(12) Patent Application Publication
(10) Pub. No.: US 2022/0325436 A1
(43) Pub. Date: Oct. 13, 2022

(54) EPITAXIAL WAFER GROWTH FURNACE, APPARATUS, MOCVD METHOD AND EPITAXIAL WAFER

(71) Applicant: KONKA GROUP CO., LTD., Shenzhen (CN)

(72) Inventors: WEIHAN LIN, SHENZHEN (CN); BANGBING LIANG, SHENZHEN (CN); MEIHUI YANG, SHENZHEN (CN)

(21) Appl. No.: 17/618,167

(22) PCT Filed: Jun. 27, 2019
(86) PCT No.: PCT/CN2019/093255

§ 371 Date: Dec. 10, 2021

(30) Foreign Application Priority Data
Jun. 11, 2019 (CN) 201910501274.1

(51) Int. Cl. C30B 25/18; H01L 21/02; C30B 25/12

(52) U.S. Cl. CPC C30B 25/186; H01L 21/0262; C30B 25/12

(57) ABSTRACT

Provided are an epitaxial wafer growth furnace, an apparatus, an MOCVD method, and an epitaxial wafer. The growth furnace comprises: a growth furnace body for placing a substrate, an upper end face of the growth furnace body is a downward concave spherical surface, and the upper end face of the spherical shape has a preset mark position; when the substrate is placed on the preset mark position and the growth furnace body rotates, a difference value of the centrifugal force applied to each part of the substrate is within a preset range. The growth furnace body is a downward concave spherical surface, such that the substrate can be placed at the position where the centrifugal force applied to each part of the substrate is equal or similar, and thus each part on the substrate has same growth stress, the epitaxial wafer with a uniform thickness is obtained.

### FIELD OF THE DISCLOSURE

The present disclosure relates to the technical field of MOCVD (Metal-Organic Chemical Vapor Deposition), and, more particularly, to an epitaxial wafer growth furnace, an apparatus, a MOCVD method and an epitaxial wafer.

### BACKGROUND

Micro LED technology, namely LED miniaturization and matrixing technology, is to prepare Micro-LED by reducing the size of LED chip to tens of microns, and hundreds and thousands of Micro-LEDs may be prepared in millimeter-scale to form Micro-LED array. Due to the micron size, Micro LED has some special photoelectric properties: good thermal diffusion effect, characteristic of supporting extremely high current density, high output optical power density, high photoelectric modulation broadband, high quantum efficiency and good reliability. The core technology of Micro LED is the transfer of nanoscale LED rather than the technology of manufacturing LED itself, including the consistency and uniformity of parameters such as light color of massive chip, the high speed and strict progress of micron level device patches, quality detection and other massive engineering.

Due to lattice matching, LED micro-devices have to be grown on a sapphire substrate by molecular beam epitaxy firstly. To make a display, it is necessary to transfer the LED light-emitting micro-devices to a glass substrate. Since the size of the sapphire substrate used to make LED micro-device is basically the size of the silicon wafer, and the glass substrate configured to make the display is much larger, multiple transfers are needed, which requires high precision, brightness and color uniformity of micro LED.

The epitaxial wafer of the LED loads a substrate in a growth furnace and rotates at high speed in a chamber of the MOCVD equipment, trimethylgallium sources such as TMGa and nitrogen are used as Ga source and N source respectively, and ultrapure hydrogen is used as carrier gas, a ternary or quaternary GaN semiconductor layer is epitaxially grown on the substrate. As shown in FIG. 1, a present growth furnace 101 is flat and circular, and a substrate 102 is based on a center and arc edges of the growth furnace. In order to make the epitaxial layer of each substrate in the chamber uniform, each substrate rotates all the time during a growth of the epitaxial layer. At the same time, due to the continuous rotation, a thickness of a single epitaxial layer may be uneven due to the action of centrifugal force, and uneven thickness of the epitaxial layer may cause unevenness in wavelength, brightness, and color coordinates.

Therefore, the present technology needs to be improved and developed.

### BRIEF SUMMARY OF THE DISCLOSURE

In view of the defects of the above prior art, the aim of the present disclosure is to provide an epitaxial wafer growth furnace, an apparatus, a MOCVD method and an epitaxial wafer, aiming to solve the problem that the thickness of a single epitaxial layer is uneven due to the rotation and centrifugal force of the substrate in the epitaxial layer growth process in the prior art.

The technical solutions adopted by the present disclosure for solving the technical problems are as follows:

An epitaxial wafer growth furnace, which comprises: a growth furnace body for placing a substrate, an upper end face of the growth furnace body is-a downward concave spherical surface, and the upper end face of the spherical surface is set with a preset mark position; and when the substrate is placed on the preset mark position and the growth furnace body rotates, the difference value of a centrifugal force applied to each part of the substrate is within a preset range.

Further, a groove is correspondingly equipped on the upper end face of the growth furnace body, the groove is used for holding the substrate.

Further, a bottom of the groove is parallel to a tangent plane at a point on the spherical surface corresponding to a center of the groove.

Further, a shaft hole is equipped in a center of the growth furnace body.

The growth furnace body rotates with an axis, and the axis is a straight line connecting the shaft hole and a sphere center of the upper end surface of the growth furnace body.

Further, a columnar side wall is connected to an edge of the upper end surface of the growth furnace body.

Further, a polyhedral side wall is connected to an edge of the upper end surface of the growth furnace body.

The disclosure further provides an apparatus, which comprises an epitaxial wafer growth furnace as mentioned above.

The disclosure further provides a MOCVD method, in which the epitaxial wafer growth furnace as mentioned above is used.

The disclosure further provides an epitaxial wafer, which is made by the MOCVD method as mentioned above.

The disclosure provides an epitaxial wafer growth furnace, an apparatus, an MOCVD method, and an epitaxial wafer. The growth furnace comprises: a growth furnace body for placing a substrate, an upper end face of the growth furnace body is a downward concave spherical surface, and the upper end face of the spherical surface is set with a preset mark position; when the substrate is placed on the preset mark position and the growth furnace body rotates, a difference value of the centrifugal force applied to each part of the substrate is within a preset range. In the present disclosure, the growth furnace body is arranged to be a downward concave spherical surface, such that the substrate may be placed at a position where the centrifugal force applied to each part of the substrate is equal or similar, and thus each part on the substrate has a same growth stress, and finally the epitaxial wafer with a uniform thickness is obtained.

### BRIEF DESCRIPTION OF THE DRAWINGS

FIG. 1 illustrates a schematic structural diagram of an embodiment of an epitaxial wafer growth furnace in the prior art.

FIG. 2 illustrates a side view of an embodiment of an epitaxial wafer growth furnace in the present disclosure.

FIG. 3 illustrates a top view of an embodiment of the epitaxial wafer growth furnace in the present disclosure.

FIG. 4 illustrates a side view of another embodiment of the epitaxial wafer growth furnace in the present disclosure.

FIG. 5 illustrates a side view of another embodiment of the epitaxial wafer growth furnace in the present disclosure.

### DETAILED DESCRIPTION OF EMBODIMENTS

In order to make the purpose, technical solution and the advantages of the present disclosure clearer and more explicit, further detailed descriptions of the present disclosure are stated here, referencing to the attached drawings and some embodiments of the present disclosure. It should be understood that the detailed embodiments of the disclosure described here are used to explain the present disclosure only, instead of limiting the present disclosure.

At present, the LED (Light-Emitting Diode) backlight technology used in the consumer electronics industries such as mobile phone, tablet and TV has been very mature. LED adapted with millimeter-scale is mainly used to provide white light source for LCD (Liquid Crystal Display) panels, the LED adapted with millimeter-scale lags behind the self-luminous OLED (Organic Light-Emitting Diode) display technology in terms of color saturation, image quality, contrast, and foldable flexibility. Therefore, major LED manufacturers have increased investment in the research and development of Micro LED display with self-illumination, Micro LED is a micro display LED at the micron level, it not only has the advantages of OLED, but also has long service life, high brightness and would not occur screen burning like OLED. The Micro LED may become the third generation display technology to replace LCD and OLED in the future. Micro LED is used in consumer electronics fields such as mobile phones and TVs, and is also suitable for outdoor display or being used in some relatively strong light conditions, such as outdoor small advertising screens, and instrument displays in automobile, high-speed rail, aircraft, shipping and so on. In addition, Micro LED has a plurality of characteristics of splicing and tailoring, which may be applied in some scenes requiring large-area and high-definition display, such as monitoring in security, smart city, smart transportation, geographic and meteorological area, or monitoring scenes of aerospace, national defense and military operations.

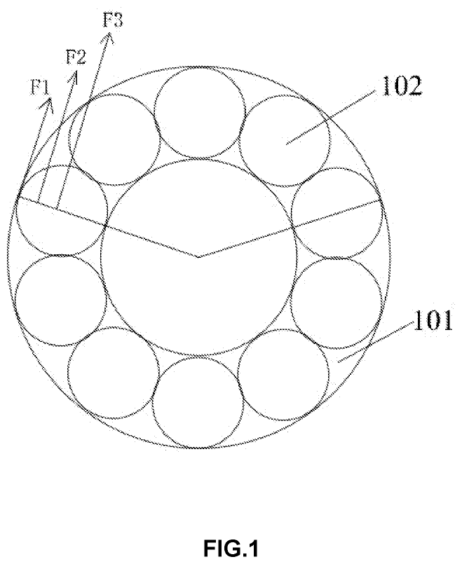

Please refer to FIG. 1, a present LED epitaxial wafer growth furnace 101 adopts a circular plane, a substrate 102 is evenly and equally spaced on a disc based on a center and an arc edge of the growth furnace, when the substrate rotates at a high speed to grow a ternary or quaternary GaN-based semiconductor layer in a chamber, a centrifugal force is circumscribed to a ring at all levels of the substrate. The closer the ring to a furnace center, the greater the centrifugal force (i.e., F3>F2>F1). The thicker a semiconductor layer (such as N-type doped layer, present spreading layer, MQW active area, P-type AIGaN layer, etc.) near the growth furnace, the better a lattice constant matching and defect quality, which ultimately leads to a plurality of parameters, such as chip wavelength, brightness and chroma, are not uniform.

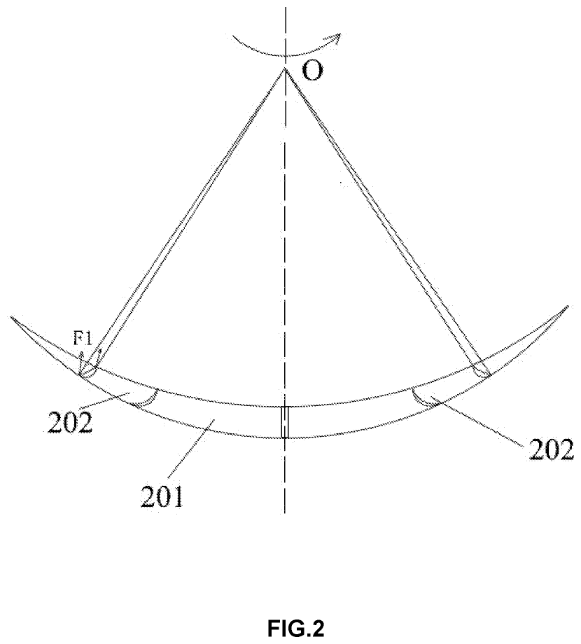

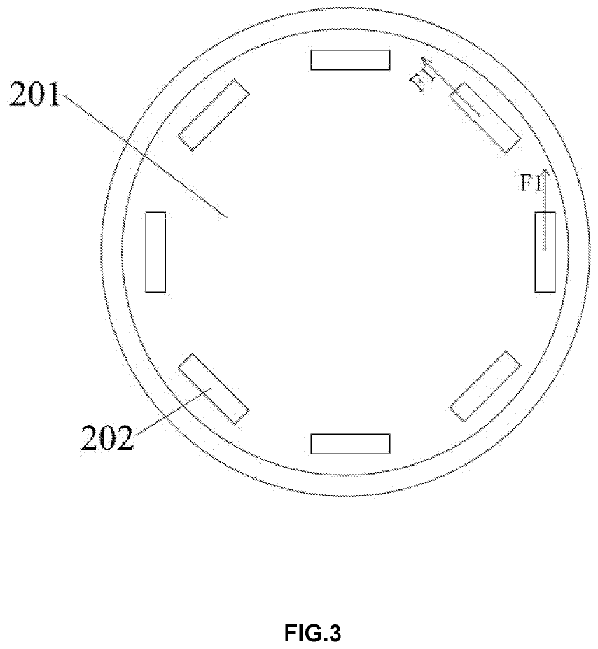

Please refer to FIG. 2 and FIG. 3, the epitaxial wafer growth furnace provided by the present disclosure comprises a growth furnace body 201 for placing a substrate 202, an upper end face of the growth furnace body 201 is a downward concave spherical surface, and the upper end face of the spherical surface has a preset mark position. When the substrate 202 is placed on the preset mark position and the growth furnace body 201 rotates, a difference value of the centrifugal force applied to each part of the substrate 202 is within a preset range. The preset marking position on the upper end surface of the growth furnace body 201 is a placement position of the substrate 202, the preset marking position may be calculated according to a curvature of the spherical surface. A position which maintains a same or similar centrifugal force on the substrate 202 is selected, where all the centrifugal forces are F1. A preset range is set in advance, as long as the difference of the centrifugal force at each part of the substrate 202 falls within the preset range, the same or similar centrifugal force at each part of the substrate 202 may be definitely achieved at the preset mark position. The upper end face of the growth furnace body 201 is a concave spherical surface, and a radius of a sphere where the spherical surface is located may be set specifically. When the radius is large, a curvature of the upper end surface of the spherical surface is small; when the radius is small, the curvature of the spherical upper end surface is large.

Since a rotation of a planar growth furnace may lead to a greater centrifugal force at the ring closer to the furnace center, resulting in uneven thickness of the epitaxial wafer. In the present disclosure, the upper end face of the growth furnace body 201 is designed as a concave spherical surface, the substrate 202 is placed on the upper end face of the growth furnace, and all parts of the epitaxial wafer have the same distance from the spherical center O of the sphere where the spherical surface is located. At a same time, the centrifugal force at high-speed rotation is basically same for all parts of the epitaxial wafer grown on the same substrate 202. When the substrate 202 rotates at a high speed to grow a ternary or quaternary GaN-based semiconductor layer in a chamber, a growth stress at all parts of the substrate 202 is same, and finally the epitaxial wafer with uniform thickness is obtained. By the present disclosure, the epitaxial wafer applied to Micro-LED with concentrated wavelength bands and uniform brightness and color coordinates may be obtained.

In an embodiment of the present disclosure, the growth furnace body 201 is a partial spherical surface with a same thickness everywhere, that is, the upper end surface of the growth furnace body 201 is an inner surface of the sphere where it is located, a lower end face of the growth furnace is an outer surface of the sphere where it is located. It can be understood that the upper end face of the growth furnace body 201 may also be designed as a downward concave spherical surface in the present disclosure, while the lower end face is in other shapes, such as a flat surface or a symmetrically designed curved surface.

Further, in the present disclosure, the preset mark position, that is, the position where the substrate 202 is placed, is to select a position with a same or similar centrifugal force according to a curved surface degree of the upper end surface of the growth furnace. It may be seen that there are a plurality of preset mark positions, the preset mark positions may be arranged on the upper end surface in a circle, with a same spacing distance between the preset mark positions, and an unlimited number of preset mark positions. In this way, the substrate 202 may be placed in a circle on the growth furnace body 201, with an unlimited number of the substrates 202, and a same spacing distance between the substrates 202 to ensure that each substrate 202 has the same centrifugal force F1.

In an embodiment of the present invention, a groove is correspondingly equipped on the upper end face of the growth furnace body 201, the groove is used for holding the substrate 202. The growth furnace body 201 has a certain thickness, and a groove for holding the substrate 202 is previously equipped on the upper end surface of the growth furnace body 201 to prevent the substrate from sliding at high speed. It can be understood that a position of the groove is also the position where the centrifugal force is the same or roughly the same everywhere.

Further, in order to maintain the same or substantially the same centrifugal force on the substrate 202 after placing the substrate in the groove, a bottom of the groove is parallel to a tangent plane at a point on the spherical surface corresponding to a center of the groove. In other words, determine the spherical center O where the upper end surface of the growth furnace body 201 is located, the center of the groove and the spherical center O are connected to form a straight line, and the straight line intersects the spherical surface at an intersection point, a tangent plane at the intersection point on the spherical surface is made, and the bottom of the groove is set as a plane parallel to the tangent plane. In this way, after the substrate 202 is placed in the groove, and the growth furnace body 201 rotates, the centrifugal force on each part of the substrate 202 may remain the same or similar.

Further, a side wall is connected to an edge of the upper end surface of the growth furnace body 201.

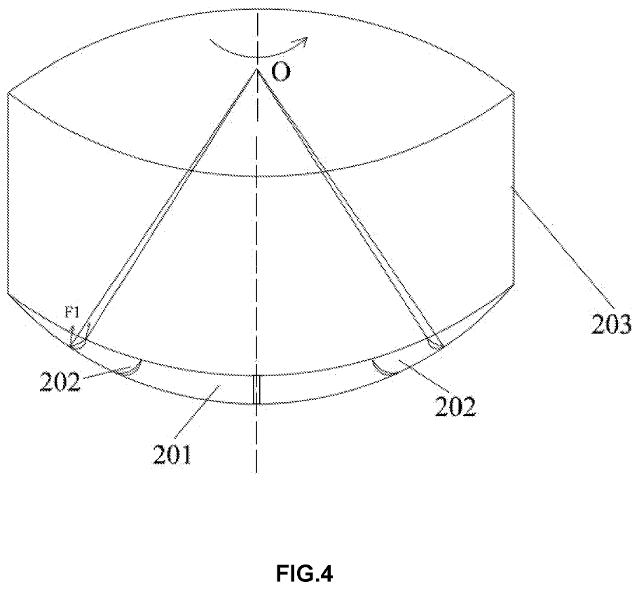

In an embodiment of the present disclosure, please refer to FIG. 4, a columnar side wall 203 is further connected to the edge of the upper end surface of the growth furnace body 201. In other words, the growth furnace body 201 is a part of a sphere, the upper part of the second growth furnace body 201 may be set as a spherical surface, or may also be set as the columnar side wall 203, that is, the side wall of the growth furnace body 201 is cylindrical, so that it may still maintain an overall balance of the growth furnace.

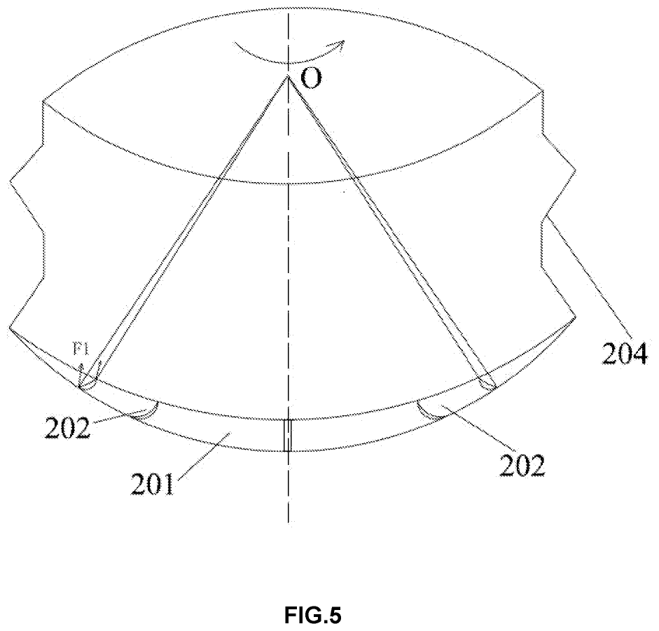

In another embodiment of the present disclosure, please refer to FIG. 5, a polyhedral side wall 204 is connected to the edge of the upper end of the growth furnace body 201, the polyhedral side wall 204 is symmetrical along an axis, which may still maintain the overall balance of the growth furnace.

The side wall in the present disclosure may also be other shapes or a combination of multiple shapes, which will not be listed here.

The present disclosure further provides an apparatus, the apparatus comprises an epitaxial wafer growth furnace as described above, the details are as described above.

The present disclosure further provides a MOCVD method, wherein the MOCVD method uses the epitaxial wafer growth furnace as described above, the details are as described above.

The MOCVD method is a new type of vapor phase epitaxial growth technology developed on a basis of vapor phase epitaxial growth (VPE), which is a method uses organic compounds of III and II elements and hydrides of V and IV elements as crystal growth source materials, achieves vapor phase epitaxy on a substrate by means of thermal decomposition reaction, and grows various thin-layer single crystal materials of main group III-V, subgroup II-VI compound semiconductors and their multiple solid solutions. Epitaxial wafers used in LED chips, various ICs, diodes, or triodes may all be obtained by the MOCVD method.

The present disclosure further provides an epitaxial wafer, which is made by the MOCVD method as described above, the details are as described above.

The epitaxial wafers prepared by the present disclosure are not limited to the LED chips LED applications require, but also include epitaxial wafers with the same manufacturing process as those in the LED chips used in various ICs, diodes, or triodes.

In summary, the present disclosure provides an epitaxial wafer growth furnace, an apparatus, an MOCuVD method, and an epitaxial wafer, the growth furnace comprises: a growth furnace body for placing a substrate, an upper end face of the growth furnace body is a downward concave spherical surface, and the upper end face of the spherical surface is set with a preset mark position; when the substrate is placed on the preset mark position and the growth furnace body rotates, a difference value of the centrifugal force applied to each part of the substrate is within a preset range. In the present disclosure, the growth furnace body is arranged to be a downward concave spherical surface, such that the substrate may be placed at the position where the centrifugal force applied to each part of the substrate is equal or similar, and thus each part on the substrate has the same growth stress, and finally the epitaxial wafer with a uniform thickness is obtained.

It should be understood that the application of the present disclosure is not limited to the above embodiments listed. Ordinary technical personnel in this field can improve or change the applications according to the above descriptions, all of these improvements and transforms should belong to the scope of protection in the appended claims of the present disclosure.

1. An epitaxial wafer growth furnace comprising:
a growth furnace body for placing a substrate, an upper end face of the growth furnace body is a downward concave spherical surface, and the upper end face of the spherical surface is set with a preset mark position;
wherein when the substrate is placed on the preset mark position and the growth furnace body rotates, a difference value of a centrifugal force applied to each part of the substrate is within a preset range.

2. The epitaxial wafer growth furnace according to claim 1, wherein a groove is correspondingly equipped on the upper end face of the growth furnace body, the groove is used for holding the substrate.

3. The epitaxial wafer growth furnace according to claim 2, wherein a bottom of the groove is parallel to a tangent plane at a point on the spherical surface corresponding to a center of the groove.

4. The epitaxial wafer growth furnace according to claim 1, wherein a shaft hole is equipped in a center of the growth furnace body.

5. The epitaxial wafer growth furnace according to claim 4, wherein the growth furnace body rotates with an axis, and the axis is a straight line connecting the shaft hole and a sphere center of the upper end surface of the growth furnace body.

6. The epitaxial wafer growth furnace according to claim 1, wherein a columnar side wall is connected to an edge of the upper end surface of the growth furnace body.

7. The epitaxial wafer growth furnace according to claim 1, wherein a polyhedral side wall is connected to an edge of the upper end surface of the growth furnace body.

8. An apparatus, wherein comprising the epitaxial wafer growth furnace according to claim 1.

9. A MOCVD method, wherein the method uses the epitaxial wafer growth furnace according to claim 1.

10. An epitaxial wafer, wherein the epitaxial wafer is made by the MOCVD method according to claim 9.
